(19) United States
(12) Patent Application Publication
(10) Pub. No.: US 2006/0238206 A1
(43) Pub. Date: Oct. 26, 2006

(54) Measuring system for the combined scanning and analysis of microtechnical components comprising electrical contacts

(75) Inventors: Lukas M Eng, Dresden (DE); Ivo Rangelow, Baunatal (DE)

Correspondence Address: HESLIN ROTHENBERG FARLEY & MESITI PC, 5 COLUMBIA CIRCLE, ALBANY, NY, 12203, US

(73) Assignee: SUSS Micro Tec Systems GmbH, Sacka (DE)

(21) Appl. No.: 10/545,776

(22) PCT Filed: Feb. 16, 2004
(86) PCT No.: PCT/DE04/00311

§ 371 Date: Apr. 24, 2006

(30) Foreign Application Priority Data
Feb. 19, 2003 (DE) 103 07 561.5

(51) Int. Cl. G01R 31/302

(52) U.S. Cl. 324/750

(57) ABSTRACT

A measuring system for the combined scanning and analysis of microtechnical components comprising electrical contacts contains a cantilever with an electrically conductive probe tip, a piezoresistive sensor that is integrated into the cantilever and a heating-wire actuator that is located in the vicinity of the probe tip. The heating-wire actuator induces mechanical oscillations in the probe tip during scanning operations and can be used during the analyses to produce a preselected tracking force, with which the probe tip lies on the component. The sensor is used during the scanning operation according to AFM methods to maintain a constant distance between the probe tip and the surface of the component and during the analyses to measure the tracking force of the probe tip on the component, and/or to adjust said force with the aid of the heating-wire actuator. A device equipped with a measuring system of this type for the combined scanning and analysis of microtechnical components is also disclosed.

The invention relates to a measuring system for combined scanning and analysis of microtechnical components comprising electrical contacts, in particular complex semi-conductor elements such as integrated circuits, for example.

Devices for analyzing or for probing microelectronic components are well-known by the designation “prober” or “probe stations” and comprise at least one measuring system with a bending beam or cantilever attached to one side, at whose free end a very fine, electrically conducting probe tip is formed. The objective in probing is to place the probe tip on selected electrical contacts or conductor tracks of the component, in order then to check, by applying electrical voltages or passage of electrical currents, whether the component has the desired functions or whether there are short circuits and/or other defects present.

Because of the increasingly smaller dimensions of microtechnical components, the component conductor tracks accessible for such tests are frequently very close to one another. Contacts and conductor tracks with widths and separations of 0.25 μm and less are no rarity. One problem arising from this situation is placing the probe tip with its diameter of 100 mm, for example, precisely on said contacts or conductor tracks.

To date the devices of the type described that are on the market have a specific mounting for installing the measuring system and which can be moved in three directions either manually or by means of a motor. As a rule, a microscope is used for facilitating or enabling the positioning of the probe tip. Optical microscopes, however, are inadequate for visualizing micro- and nano-structures and the use of electron microscopes would be associated with high costs and numerous inconveniences when probing (e.g. carrying out the measurements in a vacuum).

Devices have been described for eliminating these drawbacks [e.g. K. Krieg, R. Qi, D. Thomson und G. Bridges in “Electrical Probing of Deep Sub-Micron ICs Using Scanning Probes”, IEEE Proc. Int. Reliability Phys. Symp. IRPS (2000)], wherein the measuring system with its electrically conducting tip is built into a scanning, atomic force microscope (atomic force microscopy=AFM). In this fashion, a suitable combination device is provided both for AFM purposes and for probing purposes. An advantage herein is that the same measuring system can be used in a first procedural step for scanning, recording and electronically saving a scan image of the component surfaces to be analyzed and, using the image data obtained in the first procedural step, it can be used in a second procedural step for probing this surface. Because AFM methods make it possible to represent the topology of a surface with a resolution of 50 nm and less, the probe tip can be positioned with a correspondingly high precision when probing, without requiring optical observation of the surface. The recording of the surface topology is then done in that during scanning the probe tip is held at a constant distance form the surface (so-called “constant height mode”) and the resulting deflections of the bending beam are detected with the aid of this reflected laser beam.

The prior art devices of this type, however, do not satisfy all requirements imposed upon devices used also as a prober. For such devices, primarily the smallest possible measuring systems and accessory devices are desirable, because generally at least two, frequently even more than two probe tips must be applied at the same time on contacts or conductor tracks that are arranged in a surface zone of 1 μm or less, for example, and have separation clearances of 200 nm or less, for example. The laser optics used to date for measuring the deflection of the bending beam make this type of analyses in extremely confined spaces almost impossible. In addition, it is desirable, on the one hand when probing to place the probe tip on the contacts, conductor tracks, etc. with a certain minimum force, so that it can penetrate the oxide layers or the like present on them and on the other hand also to also limit the tracking force, in order not to damage the contacts, conductor tracks, etc. The adjustment of such a tracking force is not possible when using the bending beam comprised of a thin wolfram wire conventionally used in probes.

Starting from this state of technology, the present invention is based on the technical problem of eliminating the aforesaid problems by providing a measuring system that is suitable both for scanning using the AFM method and for probing of components by using electrical currents and/or voltages and thus can be used especially for incorporation into a device intended for both purposes.

The characteristics of claims 1 and 10 serve in the solution of this technical problem.

The invention also has the advantage that through the use of the bending beam provided with a piezoresistive force sensor according to the invention the costly and temperamental laser optics previously used for probing can now be completely eliminated. Accordingly, the result is simplified construction and clear costs savings for the device as a whole. Further advantageous is the simple electrical calibration of the piezoresistive sensor in comparison to the complicated operations generally taking several minutes that are required for precise adjustment of a laser beam onto the very small reflection surface of the bending beam Further advantageously, using the measuring system according to the invention probing can be done on surfaces reaching temperatures of up to 100° C. as is common in defect analysis of semi-conductors, because the fluctuations caused by thermal convection that must be taken into account when using laser optics are eliminated and the temperature dependence of the piezoresistive effect can be taken into account using comparatively simple means. Finally, it is also advantageous that the tracking force of the probe tip is easily measurable with the aid of the piezoresistive force sensor and can be easily adjusted with the aid of the heating-wire actuator. In addition, the invention makes possible the fabrication of the measuring system in such a way that the probe tips of a plurality of measuring systems can be positioned without difficulty at small distances on the same surface of the component.

Further advantageous characteristics of the invention are obvious from the dependent claims.

The invention will be described in more detail using exemplary embodiments in conjunction with the annexed drawings. Wherein:

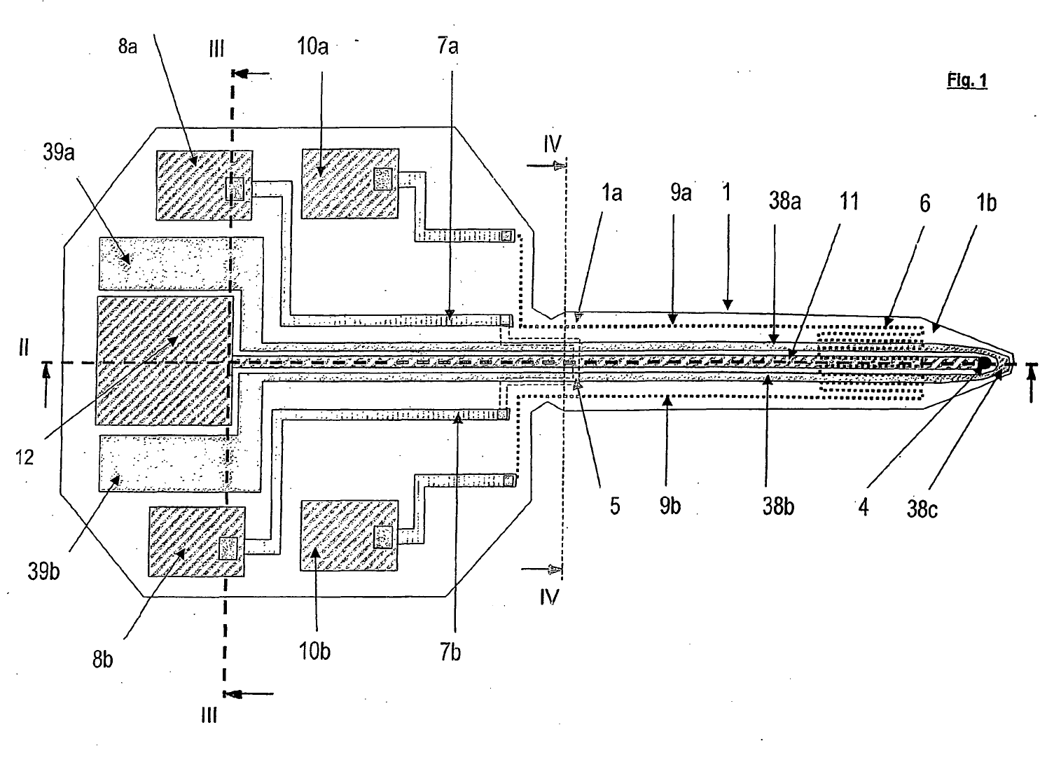

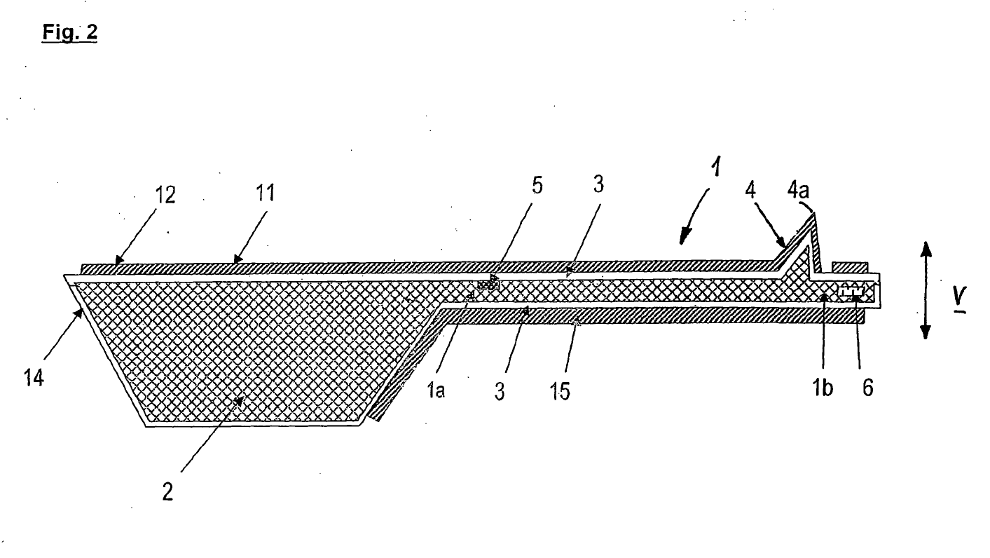

FIG. 1 represents the bottom view of a measuring system according to the invention;

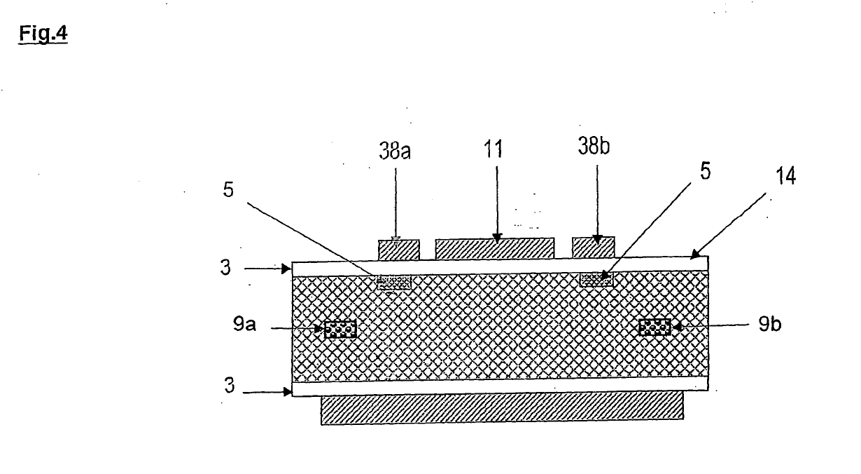

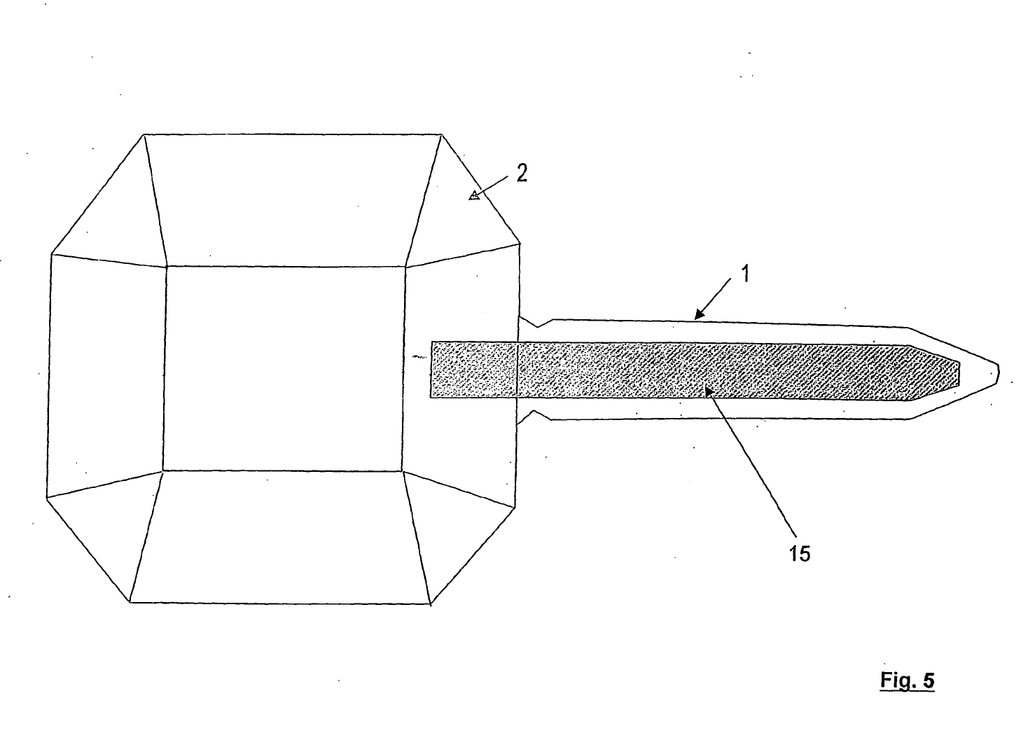

FIGS. 2 to 4 represent sections along the lines II-II to IV-IV of FIG. 1, wherein in FIG. 4 a probe tip was left out for the sake of simplicity;

FIG. 5 A top view onto the measuring system according to FIG. 1;

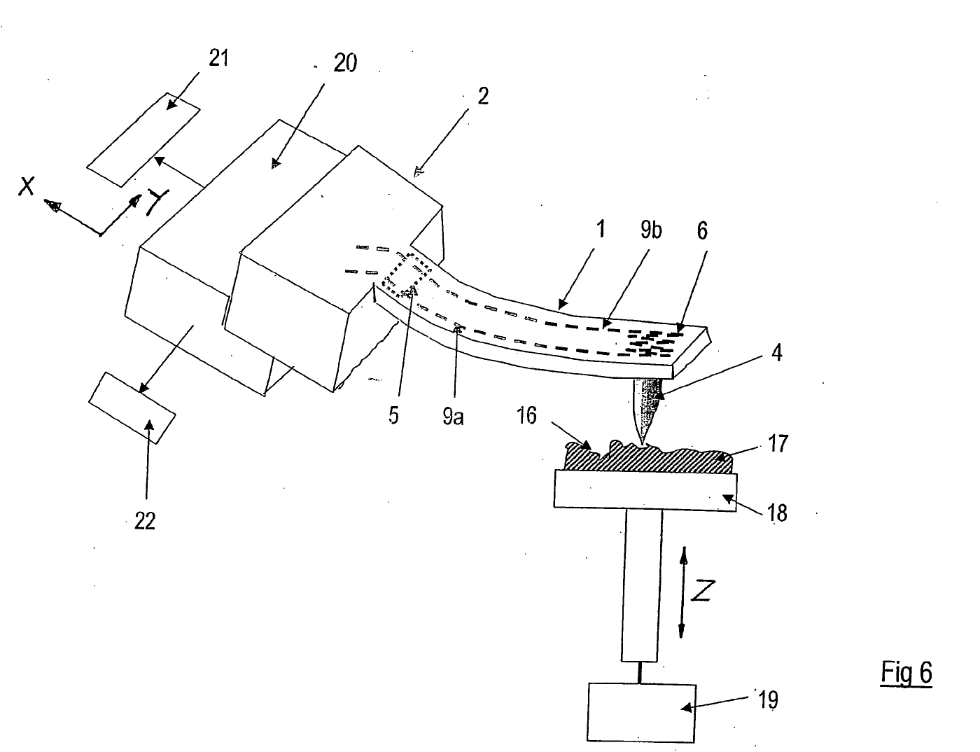

FIG. 6 diagrammatically represents the use of the measuring system according to FIGS. 1 to 4;

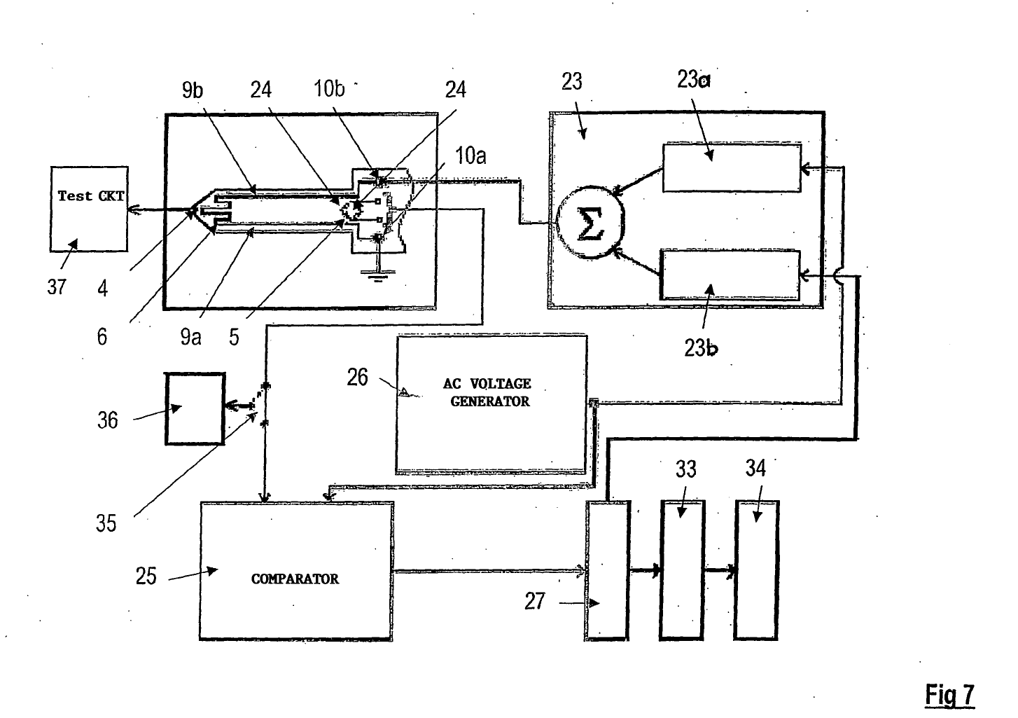

FIG. 7 diagrammatically represents a circuit configuration for the measuring system according to FIG. 6;

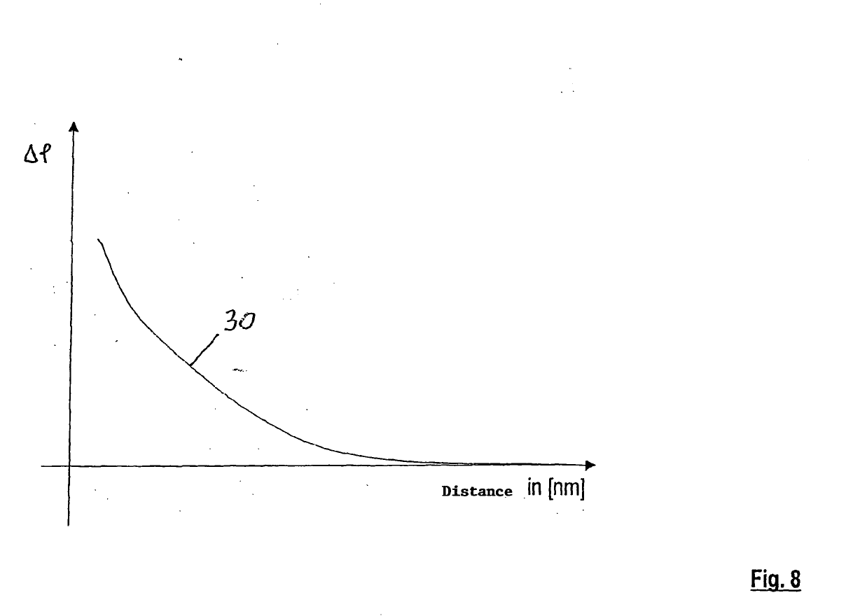

FIG. 8 represents a resonance curve for a bending beam of the measuring system according to FIG. 1;

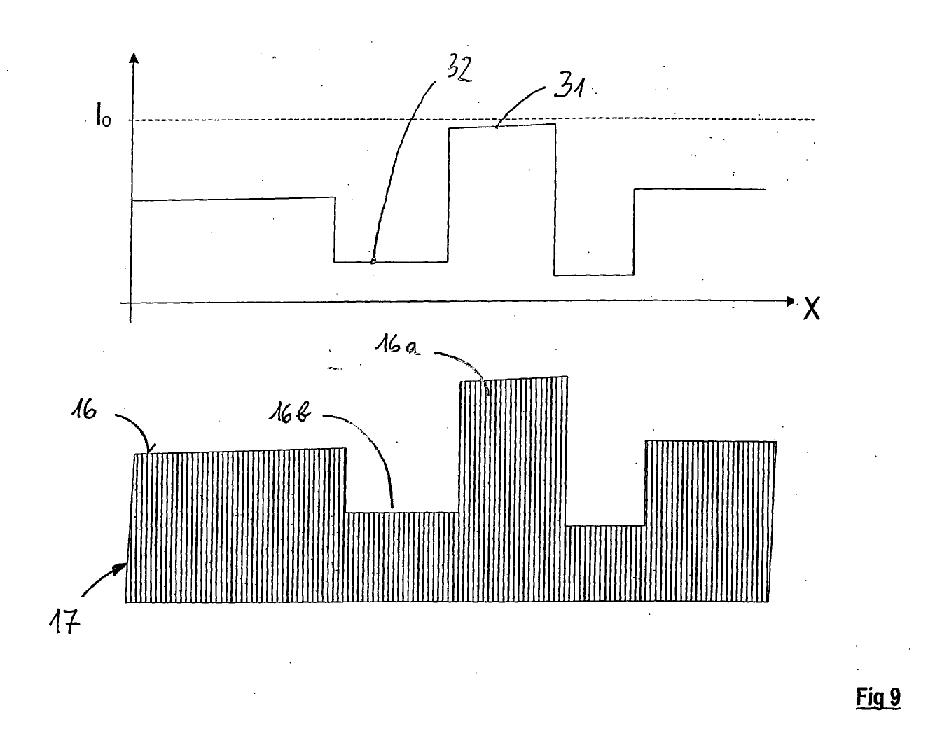

FIG. 9 represents a measurement curve obtained using the circuit configuration according to FIG. 7;

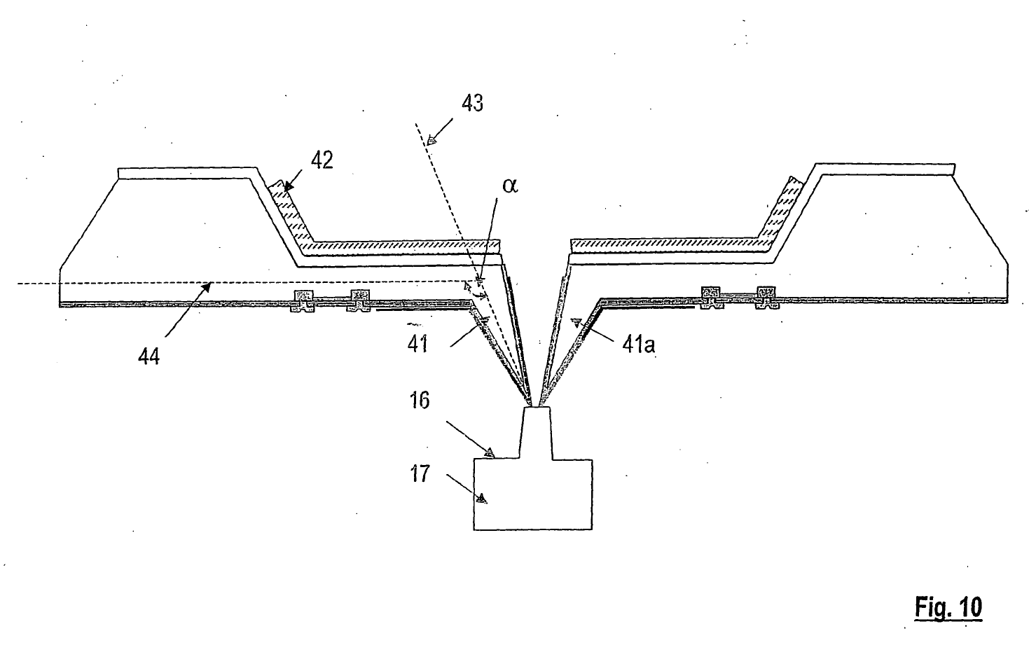

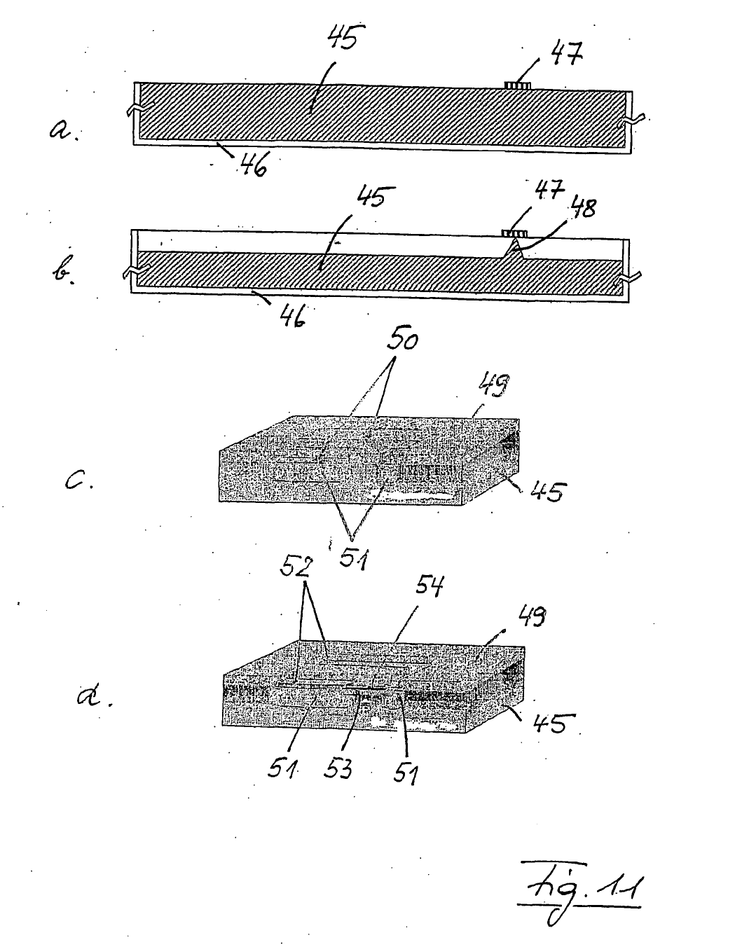

FIG. 10 represents a side view of a second embodiment of the measuring system according to the invention, and

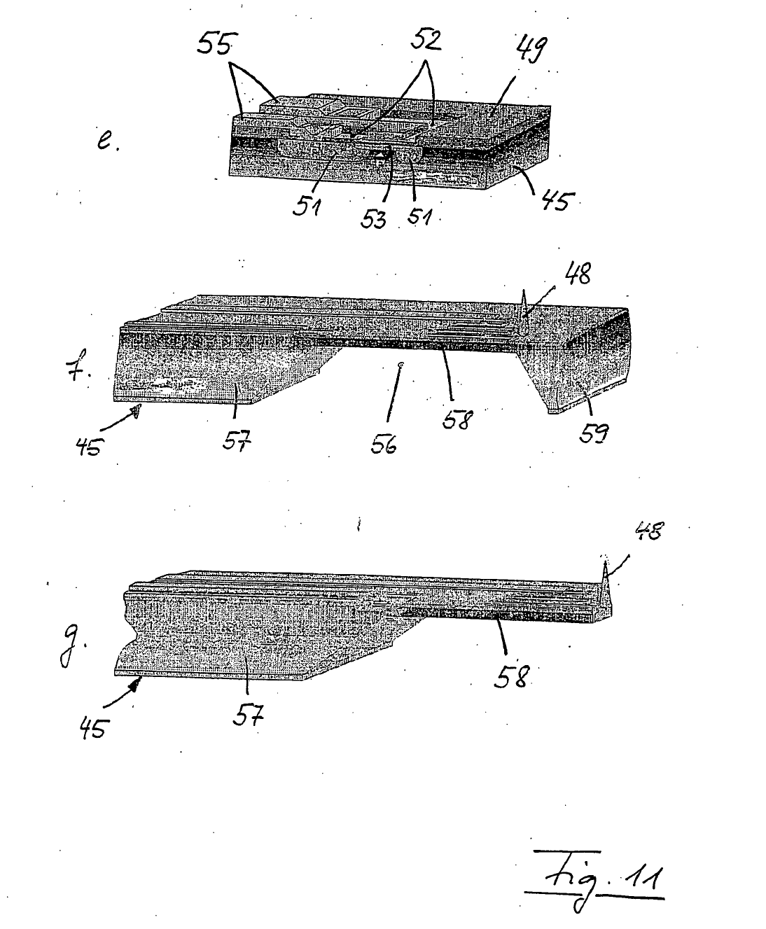

FIGS. 11a to 11g diagrammatically represents the fabrication of the measuring system according to FIGS. 1 to 4.

According to FIGS. 1 to 4, a measuring system according to the invention comprises a bending beam or cantilever 1, affixed at one side having a back end section 1a and a front end section 1b. The back end section 1a is affixed securely to a base body 2 or built into same, whereas the front end section 1b is freely arranged. The end section 1b can, therefore, upon deflection of the bending beam 1 in the direction of a double arrow v (FIG. 2), be moved up and down or may oscillate. The direction of the arrow v corresponds here, for example, to the Z-axis of a defined system of coordinates, while the directions perpendicular to it correspond to its X- and Y-axes. In addition, the bottom surface of the bending beam 1 and the bottom surface of the base body 2 running co-planar with the former are provided with a shared, isolating protective layer 3. The end section 1b has on its underside a wedge-shaped probe tip 4 projecting downward, whose extreme end running into a tip 4a has a cross section of 50-200 nm, for example. The probe tip 4 is comprised of a conducting material such as aluminum, gold, or another material with good conducting properties, for example, and is electrically isolated from the rest of the bending beam 1.

According to FIGS. 1 and 2 a piezoresistive sensor 5 is inserted into the bending beam 1, in particular in the vicinity of the stationary end section 1a. Using a sensor 5 of this type the mechanical tension inter alia that acts locally on the bending beam 1 can be calculated, because the resistance of the sensor 5 changes according to the formula:
ΔR/R=δₗΠₗ+δₜΠₜ

Here, R represents the resistance of the sensor 5, ΔR represents the change in resistance, δIₗ and δₜ the lateral or transverse voltage components and Πₗ, and Πₜ, the transverse or lateral piezoresistive coefficients (see, for example, Reichl et al. in “Halbleitersensoren” (“Semi-conductor Sensors”, expert-Verlag 198a, p. 225). Preferably, the sensor 5 is arranged at a position of the bending beam 1, where the highest mechanical tensions occur, in order to obtain a high signal/noise ratio.

The front end section 1b is further provided with a heating-wire actuator 6. This is comprised of a resistive heating element or a heating wire laid linearly or coiled or the like, which, when an electrical current is passed through it, effects a local warming of the bending beam 1 in the zone of the end section 1b.

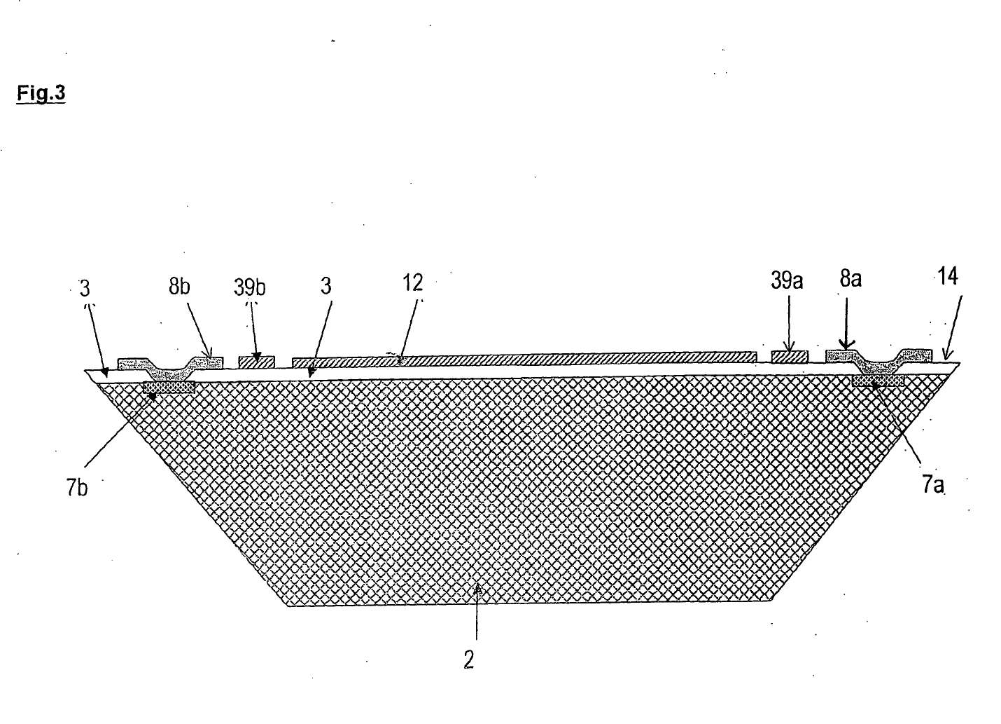

According to FIG. 1, two first feed lines 7a and 7b arranged in series are connected with the sensor 5 and like the probe end 4 are arranged on the underside of the bending beam 1 and are conductingly connected with two contact areas (“pads”) 8a and 8b arranged on the underside of the base body 2. Accordingly, the heating-wire actuator 6 is connected at two second feed lines 9a and 9b arranged in series with it and which are connected to contact areas 10a and 10b and, like the contact areas 8a, 8b, are arranged on the underside of the base body 2. Finally, a third feed line 11 is present that originates from a contact area 12 situated on the underside of the base body 2, running along the underside of the bending beam 1 to the probe tip 4 and conductingly connected with same. It is obvious here that the feed lines 7a, 7b, 9a and 9b and the contact areas 8a, 8b, 10a and 10b connected with them as well as vis-à-vis each other and also versus the probe tip 4 and its feed line 11 and contact area 12 are configured or arranged electrically isolated. To this end, the sensor 5 and the first feed lines 7a and 7b, as shown especially in FIG. 3, are arranged preferably sunken in the base body 2 and run outwards through it only in the zone of the contact areas 8a, 8b through the protective layer 3, while the feed line 11 and the contact areas 10a, 10b and 12 are arranged entirely on an open surface 14 of the protective layer 3.

Accordingly, unintended contacts in the zone of the intersection points between the different feed lines or the sensor 5 are prevented in simple fashion.

The feed line 11 and the contact areas 8a, 8b, 10a, 10b and 12 and the probe tip 4 are comprised preferably of a metal with good conductor properties such as aluminum, gold, titanium or alloys thereof, for example. In contrast, the bending beam 1 and the base body 2 are preferably comprised of a one piece silicon body and the protective layer 3 is comprised of silicon dioxide (SiO₂). The feed lines 7a, 7b arranged sunken in the base body 2 can, for example, be comprised of strongly n- and/or p-conducting zones (n⁺ or p⁺) in silicon base material. Finally, the heating wire forming the actuator 6 and the feed lines 9a, 9b are preferably microwires implanted in the bending beam 1 or the base body 2, which are connected by p⁺- or n⁺-conducting zones with the contact areas 10a, 10b.

On the top of the bending beam 1, as shown in FIG. 5, a strip 15 is applied that is comprised of a material that has a very different thermal expansion coefficient when compared to the protective layer 3 or to the base material of the beam, as is true of aluminum. Therefore, the strip 15 is comprised of a 1 μm to 3 μm thick aluminum film, for example.

According to FIG. 6 the measuring system described can be used for grid scanning of a surface 16 of a component 17 to be analyzed according to the AFM method and also for analyzing or probing the integrity of the component 17. To this end, the component 17 is placed on a table 18 of a device roughly diagrammatically represented in FIG. 6, whereby the table can be moved up and down using a Z-drive 19 in the direction of an arrow Z, which implies the Z-axis of a defined system of coordinates.

The base body 2, in contrast, is clamped in a holder 20, with the probe tip 4 arranged over the component 17, which can be moved back and forth in an XY plane of the defined system of coordinates perpendicular to the arrow Z, with each piezoelectrical X- and Y-drive 21 or 22 (only diagrammatically implied) of a conventional X/Y coordinate table. At the same time, according to FIG. 7, the heating wire actuator 6, for example, is connected by way of the contact area 10b to a power source 23 and grounded by its contact area 10a. In addition, the piezoresistive sensor 5 is preferably wired into a bridge circuit 24 (only implied diagrammatically), from which a characteristic electrical voltage is drawn for the resistance change ΔR/R of the sensor 5 or the mechanical tension of the bending beam 1. This electrical voltage is lead off to a first input of a comparator 25.

The power source 23 has on the one hand an a.c. current generator 23a connected to the output of an a.c. voltage generator 26 and on the other hand a d.c. current generator 23b connected to the output of a controller 27. The output voltage of the a.c. voltage generator 26 is also supplied to a second input of the comparator 25 as a reference voltage. An output of the comparator 25 is finally connected to an input of the controller 27.

Prior to analysis of the component 17, its surface is initially scanned using the AFM method and preferably in the so-called “no contact mode”, that is, scanned contactless, in order to obtain a picture of the surface 16 and the precise coordinates of the different contact areas and conductor tracks of the component 17 that, as a rule, protrude somewhat over the otherwise generally flat surface 16. This scanning can be done, for example, as follows: After the component 17 is placed on the table 18, the table is moved initially parallel to the Z-direction up to the stop of the surface 16 at the probe tip 4 and then gently withdrawn again some 0.55 μm, for example, so that the probe tip 4 is reliably over the highest elevation of the surface 16. With the aid of the a.c. voltage generator 23a an a.c. current is supplied to the heating-wire actuator 6, in order to periodically warm it. When this is done different thermal expansions occur to the aluminum strip 15 fastened to the bending beam 1 on the one hand and the adjacent material of the bending beam 1 or the protective layer 3 on the other hand, so that the bending beam 1 is warped with the frequency of the a.c. current in the manner of a bimetal strip or set into mechanical oscillations, wherein the amplitude of these oscillations need be only several nanometers. Then, in addition, a d.c. current is supplied to the heating-wire actuator 6 with the aid of the d.c. current generator 23b such that the bending beam 1 undergoes a homogeneous deflection parallel to the Z-axis and in the direction of the surface 16 of the component 17 and the probe tip 4 moves closer to the surface 16 up to a desired low value, without making contact with the surface. The flexure of the bending beam 1 in the Z-direction brought about by the d.c. current components can be up to several micrometers, for example.

The probe tip 4 now oscillates at the frequency of the exciting a.c. or the a.c. voltage supplied by the a.c. voltage generator 26, wherein the bending beam 1 may be thought of as a spring and the probe tip 4 as the mass of a frequency response system. The excitation of this oscillatory system is effected preferably at the resonance frequency f₀ of this frequency response system. In the undamped state, that is, when the probe tip 4 is at a large distance from the surface 16, the signal measured by the sensor would follow the exciting signal essentially without phase shift.

In fact, if the d.c. voltage components supplied to the heating-wire actuator are selected so that the probe tip 4 is situated at such a proximity to the surface 16, however, van der Waal's forces of attraction become effective, as is typical for the so-called “no-contact” mode of the AFM method. The oscillations of the bending beam 1 are accordingly damped with the result that the signal generated by the sensor 5, as demonstrated by a curve 30 shown diagrammatically in FIG. 8, follows behind the exciting signal by a specific phase angle. The magnitude of the resulting phase shift is dependent on the average measured distance in the Z-direction of the probe tip from the surface 16. According to FIG. 8, the smaller this distance the greater the phase shift Δφ is.

The probe tip 4 is now passed gridlike in the X- and Y-directions over the surface 16 as is indicated in FIG. 9 by way of example and in an exaggerated scale for the X-direction. If, when doing so, it encounters an elevation 16a or a depression 16b, then the damping changes and consequently the Δφ between the a.c. voltage generator 26 and the voltage supplied by the sensor 5. The respective phase shift Δφ is measured in the comparator 25 that is configured preferably as a PPL component (phase-locked loop). The resulting value is supplied by the comparator 25 to the controller 27, which is preferably configured as a PID controller. The latter then controls the d.c. generator 23b so that the probe tip 4 is more or less raised or lowered and accordingly the space between it and the surface 16 of the component 17 is held constant, which corresponds to the constant height mode of the AFM method. The parts 5, 25, 27, 23b and 6 thus form a closed loop system, wherein the sensor 5 determines the respective actual value, while the controller provides a target value for the distance of the probe tip 4 from the component 17.

The result of this type of control is represented diagrammatically in the upper part of FIG. 9, in which the location of the probe tip 4 in the direction of the X-axis is plotted along the abscissa and the d.c. supplied to the heating-wire actuator 6 is plotted along the ordinate. Here, a small (or larger) d.c. value in a curve segment 31 (or 32) means a minimum (or significant) deflection of the bending beam 1 in the direction of the table 18 (FIG. 6) versus a preselected zero position I₀, which is synonymous with the elevation 16a or depression 16b of the surface 16 in the Z-direction, for example. The curve segments 31, 32 thus mediate a positive picture of the scanned surface topology of the scanned component 17.

The output signal of the controller 27 or the signals corresponding to the current values in FIG. 9 are sent together with their allocated addresses in the form of X- and Y-coordinates, which are obtained with the aid of a locator (not shown) or the like, to a processing unit 33 (FIG. 7) and after appropriate processing sent as “image” data to a data memory 34. From these data and their addresses it can then be seen, where exactly the contact areas, conductor tracks or the like are arranged that are required for the subsequent probing of the component 17.

At the time of the analysis of the component as to its integrity, the device described with reference to FIGS. 6 and 7 is also used. To do this the piezoresistive sensor 5 or the bridge circuit 24 is connected by means of a switch 35 to a measuring device 36 that displays directly in digital form, for example, the mechanical tension to which the bending beam 1 is presently subjected, or displays the force, with which the probe tip presses on the surface 16 of the component 17. In addition, the probe tip 4 or the contact area 12 (FIG. 1) is connected to a test circuit 37.

At the start of each and every probe phase for the component the addresses of selected contacts of the component 17 present in the data memory 34 for addressing the X- and Y-drives 21, 22 respectively (FIG. 6) are used for the measuring system according to FIGS. 1 to 4. The probe tip 4 is then run into that position—with the aid of the X- and Y-drives 21, 22—at which an analysis is to take place, whereupon the Z- drive 19 is switched on and the component 17 is moved up to the stop at the probe tip 4. Thus, the Z-drive is activated until the measuring device 36 indicates a pre-selected tension of the bending beam 1 or a preselected tracking force, with which the probe tip 4 presses on the surface 16 or a selected contact area or the like of the component 17. This tracking force set with the aid of the measuring device 36 and signaled by means of the sensor 5 is selected so that a good electrical connection is established and the probe tip 4 penetrates any oxide layers present, which may have formed on the surface 16 or the contacts etc. of the component 17. The voltage source 23 remains turned off during probing.

After adjusting the desired tracking force of, for instance, 70-100 μN, probing of the component 17 is carried out and suitable currents or voltages are applied to the electrically conducting probe tip 4 to this end.

Probing of the component 17 can be done using direct or alternating currents or voltages. Preferably, the probing is carried out with the aid of high-frequency signals at frequencies in the mHz range. Accordingly, in order to prevent the occurrence of parasite signals and signal distortions adulterating the measurement result it is necessary to shield the probe tip 4 and the conductor track 11 leading to it. This is achieved according to the invention in that two conductor tracks 38a, 38b running parallel to it are applied on the underside of the bending beam 1 (as shown in FIGS. 1-4) on both sides of the conductor track 11, whose one ends are connected at the end segment 1b by a conductor segment 38c situated closely around the base point of the electrically conducting probe tip 4 and whose other ends are connected to contact areas 39a, 39b connected to the underside of the base body 2. The contact areas 39a, 39b are preferably grounded at the time of probing, so that the conductor tracks 38a, 38b and the conductor segment 38c act in the fashion of a coaxial line, wherein the conductor track 11 forms the so-called inner conductor, while the conductor track 38a, 38b together with the conductor segment 38c represent the so-called outer conductor. In addition, if required, by corresponding measurement and configuration of the conductor tracks 38a, 38b and 11 it can be ensured that a desired wave resistance results.

A particular advantage of the device described is that the measuring system (FIG. 1) containing the bending beam 1 includes all means for both gridlike scanning as well as for analysis of the component and the sensor 5 can be used additionally as a force measuring device at the time of probing the component 17.

As a rule, it is desirable, that the analysis of the component 17 be carried out in that at least two probe tips 4 are simultaneously pressed on contact paths or the like of the component 17 lying closely adjacent to each other. In this case, the described device is equipped with a corresponding number of measurement systems according to FIGS. 1 to 4, wherein the individual measuring systems can be set into motion independently of each other using separate X- and Y-direction drives 21, 22. When this is done, in order to be able to apply all present probe tips 4 with approximately the same tracking force on the surface 16 of the component 17, the heating-wire actuators 6 of the different measuring systems are used in the performance of an analysis with the aid of the d.c. generator 23b for heating of the different beams 1, such that the probe tips 4 move individually in the Z-direction and all probe tips 4 are applied to the component 17 with the same tracking force. The a.c. generator 23a remains turned off also in this instance during probing. Naturally, the heating-wire actuator 6 can be used even in the presence of only one probe tip 4 for the purpose of adjusting its tracking force.

In order that as many probe tips 4 as possible can be applied at the same time on the component 17 without colliding with each other, the measuring system is configured preferably as shown in FIG. 10. In this variant, which generally corresponds to the exemplary embodiment according to FIGS. 1 to 4, a probe tip 41 is not only configured at the external end of a bending beam 42 but its axis 43 is disposed also at an obtuse angle α to a middle axis 44 of the bending beam 43. Thus, a plurality of probe tips 41 and 41a (as shown in FIG. 10) can approach each other more closely than would be possible in the configuration shown in FIG. 2.

The fabrication of the measuring system with the bending beam 1 or 42 is represented diagrammatically in FIGS. 11a to 11g and can be done using the well-known method in cantilever fabrication [e.g. T. Gotszalk, J. Radojewski, P. B. Grabiec, P. Dumania, F. Shi, P. Hudek and I. W. Rangelow in “Fabrication of multipurpose piezoresistive Wheatstone bridge cantilevers with conductive microtips for electrostatic and scanning capacitance microscopy”, J. Vac. Sci. Technol. B 16 (6), Nov/Dec 1998, pp. 3948-3953 or I. W. Rangelow, P. B. Grabiec, T. Gotszalk and K. Edinger in “Piezoresistive SXM Sensors”, SIA1162,2002, pp. . . . ]. A bilaterally polished, n-conducting silicon wafer 45 or slice is used preferably as the starting material (according to FIG. 11a), whose co-planar broadsides are configured as (100)-areas and which are initially provided all round with a thermally applied SiO₂-protective layer 46. The processing of the silicon slice 45 is done according to the so-called MESA method, for example.

In the exemplary embodiment, initially the part of the protective layer 46 on the top broadside is removed by etching, whereby at a selected point a section is allowed to remain and serves as a mask 47. The exposed surface of the substrate is then (FIG. 11b) subjected to an anisotropic wet etching process, whereby the mask 47 is under-etched and a conical tip or island 48 is created. Then the surface of the silicon slice 45 is coated with a 1 μm thick SiO₂ layer 49, for example, as shown in FIG. 11c, which shows only a small section of the silicon slice 45 situated to the left of the tip 48. Windows 50 are worked into this SiO₂ layer 49 using conventional lithographic and etching methods. Through the windows 50 boron, for example is diffused in high doping into the silicon slice 45 or incorporated by ion implantation, in order to produce p⁺ conducting layers 51 underneath the windows 50, which are intended to form the implanted feed lines 7a, 7b, for example. The actuator 6 and the feed lines 9a, 9b can be formed with different dopings, if necessary, in the appropriate fashion and, if necessary, simultaneously with the layers 51 and preferably sunk into the semi-conductor slice 45 and otherwise fabricated by deep implantation or deep diffusion.

After thermal application of an additional 60 nm thick SiO₂ layer 52 (FIG. 11d), for example, for covering of the layers 51, these can be connected at a selected point, at which the piezoresistive sensor 5 is to be arranged, by means of a p-conducting layer 53 (FIG. 11d), in that the SiO₂ layer 52 is provided with a window 54, through which the boron or the like is diffused or implanted using low doping into the silicon slice 45. The layer 53 produced in this fashion is activated by heating or the like and then forms the piezoresistive sensor 5 (FIGS. 1, 2 and 4).

By the use of analogous processes (lithography, oxide etching, etc.) the sections of the p⁺-layers are then exposed that are to be provided with metal contacts. After this is done, the entire surface of the silicon slice 45 is coated with a metal such as aluminum, for example, which then is etched away using a suitable etching agent (e.g. phosphoric acid) everywhere, where it is not needed (FIG. 11e). Therefore, only the actual conductor tracks 55 or contact areas remain intact (e.g. 8a, 8b, etc. in FIG. 1). The conductor tracks 11 and 38a, 38b can be fabricated in corresponding fashion. In this step the tip 48 (FIG. 11b) is also coated with the metal used and is thus made electrically conducting.

After the different feed lines shown in FIGS. 1 to 4 are fabricated, the silicon slice 45 is processed form the opposite broadside using suitable lithography and etching methods, in order to form a recess 56 (FIG. 11f) in the silicon slice 45 or, for example, to leave intact only a 10 to 30 μm, thin, membrane 58 of the silicon slice 45 forming the bending beam 1 (FIG. 2) and carrying the tip 48 (FIG. 11b), adjacent to a section 57 forming the base body 2. In a last step, a section 59 of the semi-conductor slice 45 that is arranged on the opposite side of the recess 56 in comparison to the section 57, is removed by dry etching or the like using SF₆/Ar or SF₆/CCI₂F₂/Ar, for example, whereby the finished measuring system is obtained (FIG. 11g) as shown in FIGS. 1 to 5. Thus, for example, a temporarily applied 8 μm thick protective layer (e.g. AZ 4562) can be used as an etching mask on the broadside provided with the tip 48.

It is otherwise clear that referring to FIGS. 11a to 11g the process steps described represent merely examples, that may be replaced by any number of process steps well-known to the person skilled in the art. The same applies also to the layers described herein or others intended for protection or sealing.

The invention is not limited to the exemplary embodiments described which can be transformed in many different ways. This applies especially to the indicted forms, dimensions and materials of the measuring system according to the invention. For example, it is possible to integrate the bridge circuit 24 (FIG. 6) entirely in the bending beam 1 or in the base body 2 or to apply the actual sensor 5 in the bending beam 1 while applying the other parts of the bridge circuit 34 external to the measuring system. Furthermore, the described fabrication method is intended only as an example, because there are numerous other methods for fabricating the cantilever and its associated parts. Furthermore, the feed lines 9a, 9b and the heating-wire actuator 6 can, as shown in FIGS. 2 and 4, be more or less separated far from the aluminum strip 15. It is even possible to arrange the feed lines 9a, 9b and the heating-wire actuator 6 in the vicinity of the surface 14 and thus substantially co-planar with the feed line 11 and to use it as shielding at the time of probing. In this case, the conductor tracks 38a, 38b could be eliminated completely. Nevertheless, the heating-wire actuator 6 could also be used at the time of probing, because here it carries a direct current, which does not essentially impair the desired shielding effect. In addition, it is obvious, that the different characteristics can be used in combinations other than those represented and described herein.

1. A measuring system for combined scanning and analysis of microtechnical components comprising electrical contacts, and having: a base body, a bending beam having a first end section fixedly attached to the base body and a second, free end section provided with an electrically conducting probe tip, a piezoresistive sensor integrated in the bending beam between the first and second end sections, a heating-wire actuator for deflection of the bending beam, first feed lines connected with the sensor, second feed lines connected to the heating-wire actuator and a third feed line connected to the probe tip, wherein the first, second and third feed lines are comprised of conductor tracks arranged on or in the bending beam and the first and second feed lines are electrically isolated from each other and from the probe tip and the third feed line.

2. The measuring system according to claim 1, wherein the heating-wire actuator and the second feed lines are configured as shielding for the third feed line.

3. The measuring system according to claim 2, wherein the second feed lines are configured co-planar with the third feed line.

4. The measuring system according to claim 1, wherein shielding conductor tracks are arranged on both sides of the third feed line, said shielding conductor tracks, together with a conductor segment connecting said shielding conductor tracks and situated adjacent a base of the probe tip, form a shielding for the third feed line.

5. The measuring system according to claim 4, wherein the first, second and third feed lines and the shielding conductor tracks are arranged on an underside of the bending beam.

6. The measuring system according to claim 1, wherein the probe tip is arranged at a far end of the free end section of the bending beam and has a central axis at an obtuse angle with a longitudinal axis of the bending beam.

7. The measuring system according to one of claim 1, wherein on an upper side of the bending beam, a strip is formed from a material that has a thermal expansion coefficient that differs from that of the bending beam and/or of a protective layer on the bending beam.

8. The measuring system according to claim 7, wherein the thermal expansion coefficient of the strip is greater than that of the bending beam and/or the protective layer.

9. The measuring system according to claim 7, wherein the bending beam comprises silicon, the protective layer out comprises silicon dioxide and the strip comprises a metal.

10. A device for combined scanning and analysis of a microtechnical component comprising a table displaceable in a Z-direction for receiving the component, at least one holder that can be moved in the X- and Y-directions and having a measuring system according to claim 1, a control circuit connected to the first and second feed lines for controlling current supply to the heating-wire actuator in such a way that a distance of the probe tip from a surface of the component remains essentially constant when scanning, means for acquiring and storing data and addresses in the X- and Y-directions corresponding to a topology of the surface of the component at a time of scanning, means for displacing the holder in the X- and Y-directions at the time of scanning and for approaching selected zones of the surface at a time of analysis using the stored data and addresses, means connected to the first and second feed lines for supporting the probe tip with a pre-selected tracking force on the surface at the time of analysis, and at least one testing device connected to the third feed line for carrying out the analysis.

11. The measuring system according to claim 9, wherein the strip comprises aluminum.
